(19) United States
(12) Patent Application Publication
(10) Pub. No.: US 2012/0216869 A1
(43) Pub. Date: Aug. 30, 2012

(54) ORGANIC PHOTOVOLTAIC CELL AND METHOD FOR MANUFACTURING THE SAME

(76) Inventors: Takehito Kato, Oyama-shi (JP); Toshihiro Ohnishi, Tsukuba-shi (JP)

(21) Appl. No.: 13/504,802

(22) PCT Filed: Oct. 26, 2010
(86) PCT No.: PCT/JP2010/068955

§ 371 Date: Apr. 27, 2012

(30) Foreign Application Priority Data
Oct. 30, 2009 (JP) 2009-250224

(51) Int. Cl. H01L 51/44; H01L 51/48

(52) U.S. Cl. 136/263; 438/82; 257/E51.012

(57) ABSTRACT

An organic photovoltaic cell comprising: an operative part containing a pair of electrodes and an active layer that is located between the pair of electrodes and containing an organic compound; and a sealing layer covering at least a part of the operative part, in which the sealing layer contains a substance having an oxygen absorption property and/or a water absorption property has excellent photovoltaic efficiency.

### TECHNICAL FIELD

The present invention relates to an organic photovoltaic cell and a method for manufacturing the same.

### BACKGROUND ART

Organic photovoltaic cell have advantages such as their simple structures and manufacturing facility at low cost due to reason that organic photovoltaic cells can be formed by printing and the like, in comparison with other devices such as an inorganic photovoltaic cell. However, poor photovoltaic efficiency hampers practical use of the organic photovoltaic cell.

The organic photovoltaic cell has an active metal electrode in at least one of electrodes and electrons or holes are flown through an organic material/metal interface. Consequently, chemical change of the interface may generate barrier for charge transfer. This chemical change is caused by reaction of oxygen or water with a metal. Therefore, it is expected that lifetime can be extended by removing oxygen and/or water, particularly water. In order to reduce influence of oxygen and moisture (humidity) on the organic photovoltaic cell, a substrate having high barrier properties is usually adhered to the organic photovoltaic cell. For the adhesion, a light- or heat-curing type sealant is used. However, water and oxygen may also penetrate through the sealant, and this leads to reduction in lifetime.

Patent Literature 1 discloses that influence of moisture and oxygen can be blocked by stacking an inorganic sealing layer formed by a vapor phase film formation method and a surface protecting layer made of a resin layer formed on the inorganic sealing layer on the surface of an organic photovoltaic cell.

### CITATION LIST

### Patent Literature

Patent Literature 1: JP 2004-165512 A

### DISCLOSURE OF INVENTION

### Technical Problem

However, there has been a problem in which the surface protecting layer according to Patent Literature 1 is easy to deteriorate by ultraviolet light, whereby penetration of water and oxygen into a cell cannot sufficiently be prevented.

The present invention eliminates deterioration caused by ultraviolet light and provides an organic cell that has excellent photovoltaic efficiency.

The present invention provides aspects [1] to [6] described below.

[1] An organic photovoltaic cell comprising:

an operative part that comprises a pair of electrodes and an active layer that is located between the pair of electrodes and comprises an organic compound; and

a sealing layer covering at least a part of the operative part, wherein

the sealing layer comprises a substance having an oxygen absorption property and/or a water absorption property.

[2] The organic photovoltaic cell according to above [1], wherein the substance having the oxygen absorption property and/or the water absorption property is a metal oxide.

[3] The organic photovoltaic cell according to above [2], wherein the metal oxide is calcium oxide.

[4] The organic photovoltaic cell according to any one of above [1] to [3], wherein the substance having the oxygen absorption property and/or the water absorption property is a particle having a particle diameter of 1 μm or less.

[5] The organic photovoltaic cell according to any one of above [1] to [4], wherein a substrate is mounted on the sealing layer.

[6] A method for manufacturing an organic photovoltaic cell, the method comprising:

covering at least a part of an operative part with a sealing layer, the operative part comprising a pair of electrodes and an active layer that is located between the pair of electrodes and comprises an organic compound, the sealing layer comprising a substance having an oxygen absorption property and/or a water absorption property.

### BRIEF DESCRIPTION OF DRAWINGS

FIG. 1 depicts one example of layer structure of the organic photovoltaic cell according to the present invention.

FIG. 2 depicts another example of layer constitution of the organic photovoltaic cell according to the present invention.

FIG. 3 depicts another example of layer constitution of the organic photovoltaic cell according to the present invention.

FIG. 4 depicts another example of layer constitution of the organic photovoltaic cell according to the present invention.

FIG. 5 depicts another example of layer constitution of the organic photovoltaic cell according to the present invention.

FIG. 6 is a graph illustrating current-voltage properties of each organic thin film solar cell of Example 1 and Comparative Example 1.

FIG. 7 is a graph illustrating current-voltage properties of each organic thin film solar cell of Example 2 and Comparative Example 2.

### EXPLANATIONS OF LETTERS OR NUMERALS

10 Organic Photovoltaic Cell

20 Substrate

32 First Electrode

34 Second Electrode

40 Active Layer

42 First Active Layer

44 Second Active Layer

52 First Intermediate Layer

54 Second Intermediate Layer

50 Sealing Layer

60 Substrate

70 Operative Part

### DESCRIPTION OF EMBODIMENT

Contraction scales of each member in the drawings illustrated in the following description may differ from actual scales. Although members such as lead wires of electrodes also exist in the organic photovoltaic cell, description and illustration of these members are omitted because these members do not directly relate to description of the present invention.

Basic constitution of the organic photovoltaic cell of the present invention is constitution having a pair of electrodes, an active layer, and a sealing layer. At least one of the pair of electrodes is transparent or translucent. In the organic photovoltaic cell, the transparent or translucent electrode in the pair of electrodes is usually an anode. In the pair of electrodes, the electrode that may be neither transparent nor translucent is usually a cathode. A position of the active layer in the organic photovoltaic cell is usually between the pair of electrodes. The active layer may be one layer. However, the active layer may also be a plurality of layers. A layer other than the active layer may also be located between the pair of electrodes. This layer may be referred to as an interlayer in the present description.

The active layer is a layer comprising organic compound. Examples of the organic compound may include an electron-donor compound (a p-type semiconductor) and an electron-acceptor compound (an n-type semiconductor). The active layer may be a single layer or a layered body made by stacking a plurality of layers. Examples of forms of the active layer may include an active layer of what is called pn hetero-junction type in which a layer formed by an electron-donor compound (an electron-donor layer) and a layer formed by an electron-acceptor compound (an electron-acceptor layer) are stacked; an active layer of bulk hetero junction type in which a bulk hetero junction structure is formed by mixing the electron-donor compound and the electron-acceptor compound; and the like. Any of the forms may be applicable for the active layer in the present invention.

In the present description, the pair of electrodes, the active layer and the interlayer that is optionally located may be collectively referred to as an operative part.

The sealing layer is a layer that covers at least a part of the operative part. Embodiments of the sealing layer may include an embodiment that surrounds circumference of the operative part, and an embodiment that covers a surface of any one of the electrodes.

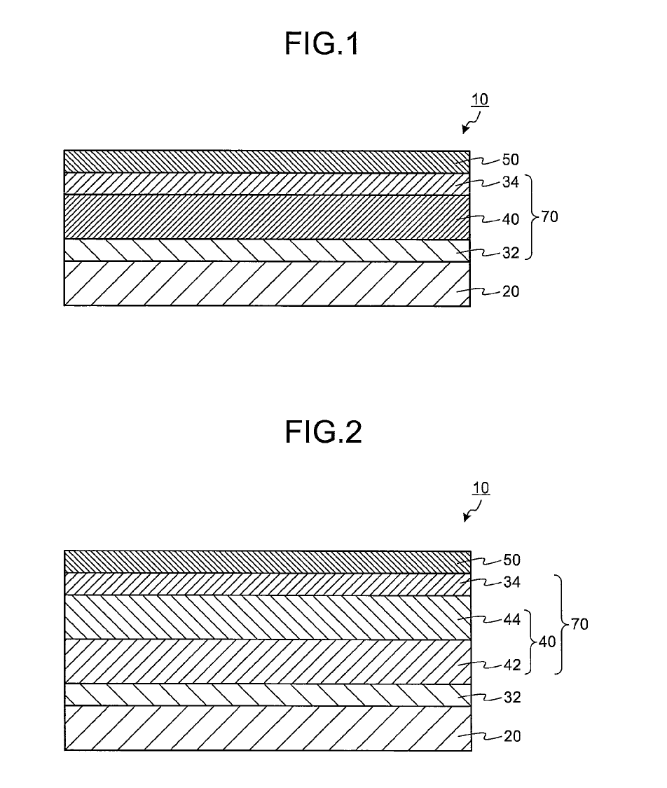

Examples of the layer structure of the organic photovoltaic cell are described with reference to FIGS. 1 to 5. Each of FIGS. 1 to 5 illustrates an example of the layer structure of the organic photovoltaic cell. Hereinafter, FIG. 1 is explained first, FIG. 2 is then explained only on the differences from FIG. 1. In the subsequent description, differences in the drawing from the drawing having a smaller drawing number are only described.

In an example in FIG. 1, an organic photovoltaic cell 10 is constituted by mounting a layered body in which an active layer 40 is sandwiched between a first electrode 32 and a second electrode 34 on a substrate 20. When light is taken from the substrate 20 side, the substrate 20 is transparent or translucent. The surface of the second electrode 34 is covered with a sealing layer 50.

Usually, at least one of the first electrode 32 and the second electrode 34 is transparent or translucent. When light is taken from the substrate 20 side, the first electrode 32 is transparent or translucent.

Which of the first electrode 32 and the second electrode 34 is an anode and which of those is a cathode are not particularly limited. For example, when the organic photovoltaic cell 10 is manufactured by sequentially stacking from the substrate 20 side, in the case that a deposition method is used for film formation of a cathode (for example, aluminum or the like), the deposition may preferably be performed in a later process. Therefore, in this example, it is preferable that the first electrode 32 is an anode and the second electrode 34 is a cathode. In this example, the aluminum electrode may be difficult to be transparent or translucent depending on setting of its thickness. Therefore, in order to be possible to take light from the substrate 20 side, the substrate 20 and the first electrode 32 are preferably formed transparent or translucent.

In an example of FIG. 2, the active layer 40 is constituted by two layers of a first active layer 42 and a second active layer 44, and is a pn hetero-junction type active layer. Either layer of the first active layer 42 and the second active layer 44 is an electron-acceptor layer and Either other layer is an electron-donor layer.

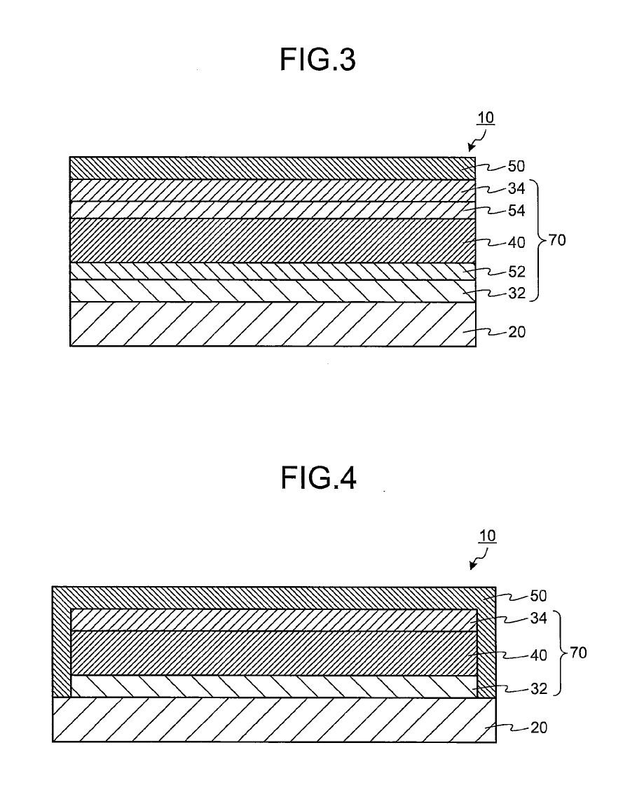

In an example of FIG. 3, a first interlayer 52 and a second interlayer 54 are provided. The first interlayer 52 and the second interlayer 54 are located between the active layer 40 and the first electrode 32 and between the active layer 40 and the second electrode 34, respectively. It is also possible that either the first interlayer 52 or the second interlayer 54 be located. In FIG. 3, each interlayer is illustrated as a single layer. However, each interlayer may be constituted by a plurality of layers.

The interlayer may have various functions. When the first electrode 32 is assumed as an anode, the first interlayer 52 may be, for example, a hole transport layer, an electron block layer, a hole injection layer, or a layer having other function. In this case, the second electrode 34 is a cathode, and the second interlayer 54 may serve as, for example, an electron transport layer, an electron block layer, and a layer having other function. On the contrary, when the first electrode 32 is a cathode and the second electrode 34 is an anode, the interlayers switches respective positions each other in accordance with this alteration.

In an example in FIG. 4, the sealing layer 50 covers not only the second electrode 32, but also the side surfaces of the active layer 40 and the first electrode 32. As described above, the sealing layer 50 may cover the side surface of the operative part 70.

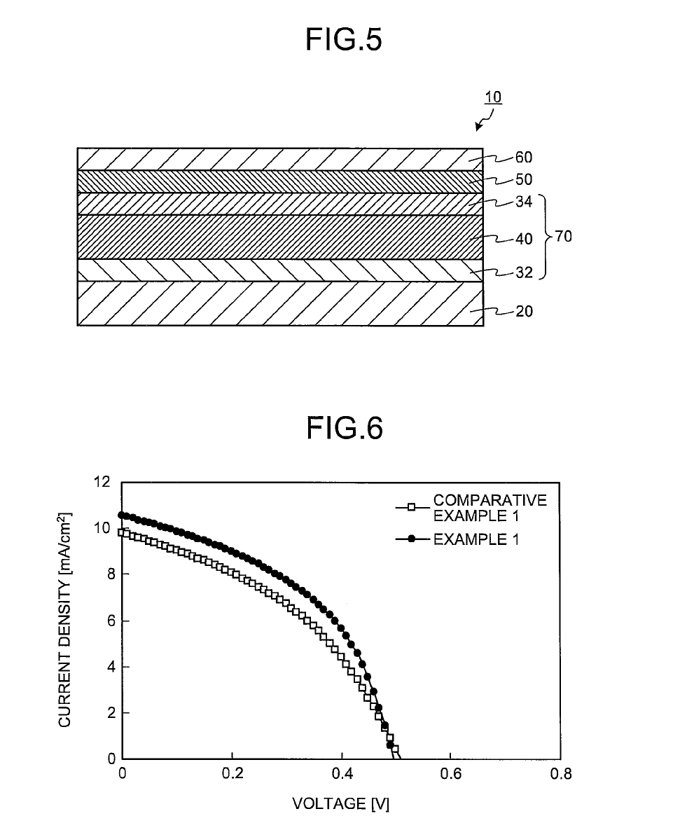

In an example in FIG. 5, a substrate 60 is mounted on the sealing layer 50. In this case, it is preferable that the sealing layer 50 is a layer having adhesion properties and bonding the substrate 60. It goes without saying that it is not essential that the sealing layer 50 has the adhesion properties. It is also possible that the sealing layer 50 and the substrate 60 are bonded by inserting an adhesive (not illustrated).

The organic photovoltaic cell of the present invention is the above-described organic photovoltaic cell, and an organic photovoltaic cell in which the sealing layer comprises a substance having an oxygen absorption property and/or a water absorption property.

The substances having the oxygen absorption property and/or the water absorption property may include three types of substances, that is, a substance indicating the oxygen absorption property, a substance indicating the water absorption property, or a substance indicating the oxygen absorption property and the water absorption property. In the present invention, either one of these substances or combination of two or more of these substances may be used.

Examples of the substances having the oxygen absorption property and/or the water absorption property may include metal oxides and silica gel. Examples of the metal oxides may include calcium oxide, titanium oxide, aluminum oxide, molybdenum oxide, magnesium oxide, and barium oxide. Among them, the metal oxides are preferable, and calcium oxide (CaO) is preferable.

The substance having the oxygen absorption property and/or the water absorption property is usually particles. The particle preferably has a particle diameter of 1 μm or less. The particle more preferably has a particle diameter of 0.5 μm or less. The particle further more preferably has a particle diameter of 0.1 μm or less.

The sealing layer may be any layer so long as it comprising a substance having the oxygen absorption property and/or the water absorption property. Example of the substance may include a resin in the form of dispersing the substance having the oxygen absorption property and/or the water absorption property. Examples of the resins may include an ultraviolet curing resin, a thermosetting resin, and a two-component mixing type epoxy resin. Examples of the ultraviolet curing resins may include an epoxy-based resin, a polyester-based resin, and a urethane-based resin. Among them, the ultraviolet curing resin is preferable and the epoxy-based resin is more preferable.

The sealing layer preferably has adhesion properties. Accordingly, the substrate can directly be bonded on the sealing layer without using an adhesive. Consequently, further extension of lifetime of the organic photovoltaic cell can be achieved by further preventing penetration of water and/or oxygen. Examples of the materials having adhesion properties may include, among the resins described above, the ultraviolet curing resin, the thermosetting resin, and the two-component mixing type epoxy resin. Among them, the ultraviolet curing resin is preferable and the epoxy-based resin is more preferable.

The thickness of the sealing layer is usually 1 μm to 500 μm, preferably 10 μm to 250 μm, and more preferably 50 μm to 150 μm.

The organic photovoltaic cell of the present invention comprises, in addition to the sealing layer described above, an operative part having a pair of electrodes in which at least one electrode is transparent or translucent, and an active layer that is located between the pair of electrodes and comprises an organic compound.

Examples of the electrode materials constituting the transparent or translucent electrodes may include a conductive metal oxide film and a translucent thin metal film. Specific examples may include films made of conductive materials such as indium oxide, zinc oxide, tin oxide, and complex materials made of two or more of these oxides (examples: indium-tin oxide (ITO), indium-zinc oxide (IZO), and NESA); thin metal films of gold, platinum, silver, copper, and the like. Films made of the conductive materials such as ITO, indium-zinc oxide, tin oxide, and the like are preferable. Examples of methods for preparing the electrode may include a vacuum evaporation method, a sputtering method, an ion plating method, and a plating method. As the electrode material, organic transparent conductive films such as polyaniline and a derivative thereof and polythiophene and a derivative thereof may be used.

A counterpart electrode of the transparent or semi-transparent electrode may be transparent or translucent, as well as the counterpart electrode may be neither transparent nor translucent. Examples of electrode materials constituting the electrode may include metals and conductive macromolecules. Specific examples of the electrode materials may include metals such as lithium, sodium, potassium, rubidium, cesium, magnesium, calcium, strontium, barium, aluminum, scandium, vanadium, zinc, yttrium, indium, cerium, samarium, europium, terbium and ytterbium; and alloys made of two or more of these metals; alloys made of one or more of these metal(s) and one or more metal(s) selected from the group consisting of gold, silver, platinum, copper, manganese, titanium, cobalt, nickel, tungsten and tin; graphite and intercalated graphite; polyaniline and a derivative thereof, and polythiophene and a derivative thereof. Examples of the alloys may include a magnesium-silver alloy, a magnesium-indium alloy, a magnesium-aluminum alloy, an indium-silver alloy, a lithium-aluminum alloy, a lithium-magnesium alloy, a lithium-indium ally, and a calcium-aluminum alloy.

The active layer is a layer comprising an organic compound. Examples of the organic compound comprised in the active layer may include, as described above, a combination of the electron-donor compound and the electron-acceptor compound. The electron-donor compound and the electron-acceptor compound are not particularly limited, and can be relatively determined by energy level of these compounds.

Examples of the electron-donor compound may include pyrazoline derivatives, arylamine derivatives, stilbene derivatives, triphenyldiamine derivatives, oligothiophene and derivatives thereof, polyvinylcarbazole and derivatives thereof, polysilane and derivatives thereof, polysiloxane derivatives having aromatic amines in the main chain or side chains thereof, polyaniline and derivatives thereof, polythiophene and derivatives thereof, polypyrrole and derivatives thereof, polyphenylene vinylene and derivatives thereof, and polythienylene vinylene and derivatives thereof. Among them, the oligothiophene and the derivatives thereof are preferable and, poly (3-hexyl thiophene) (P3HT) is more preferable.

On the other hand, compounds having structural units represented by the following Chemical Formula (1) are also preferable as the electron-donor compound.

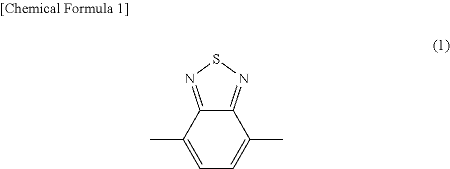

The compound having the structural units represented by Chemical Formula (1) preferably further has structural units represented by Chemical Formula (2).

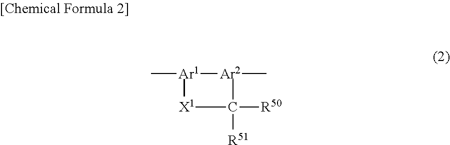

In Chemical Formula (2), Ar¹ and Ar² are the same as or different from each other, and represent a trivalent heterocyclic ring. X¹ represents —O—, —S—, —C(═O)—, —S(═O)—, —SO₂—, —Si(R³)(R⁴)—, —N(R⁵)—, —B(R⁶)—, —P(R⁷)— or —P(═O)(R⁸)—. R³, R⁴, R⁵, R⁶, R⁷ and R⁸ are the same as or different from each other, and represent a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an imino group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵⁰ represents a hydrogen atom, a halogen atom, an alkyl group, an alkyloxy group, an alkylthio group, an aryl group, an aryloxy group, an arylthio group, an arylalkyl group, an arylalkyloxy group, an arylalkylthio group, an acyl group, an acyloxy group, an amido group, an acid imido group, an imino group, an amino group, a substituted amino group, a substituted silyl group, a substituted silyloxy group, a substituted silylthio group, a substituted silylamino group, a monovalent heterocyclic group, a heterocyclyloxy group, a heterocyclylthio group, an arylalkenyl group, an arylalkynyl group, a carboxyl group, or a cyano group. R⁵¹ represents an alkyl group having six or more carbon atoms, an alkyloxy group having six or more carbon atoms, an alkylthio group having six or more carbon atoms, an aryl group having six or more carbon atoms, an aryloxy group having six or more carbon atoms, an arylthio group having six or more carbon atoms, an arylalkyl group having seven or more carbon atoms, an arylalkyloxy group having seven or more carbon atoms, an arylalkylthio group having seven or more carbon atoms, an acyl group having six or more carbon atoms, or an acyloxy group having six or more carbon atoms. X¹ and Ar² are bonded to adjacent sites on a heterocycle contained in Ar¹, and C(R⁵⁰) (R⁵¹) and Ar¹ are bonded to adjacent sites on a heterocycle contained in Ar².

Examples of such compounds having the structural unit represented by Chemical Formula (1) may include a polymer (hereinafter referred to as a macromolecular compound A) obtained by polymerizing a compound represented by Chemical Formula (3) and a compound represented by Chemical Formula (4).

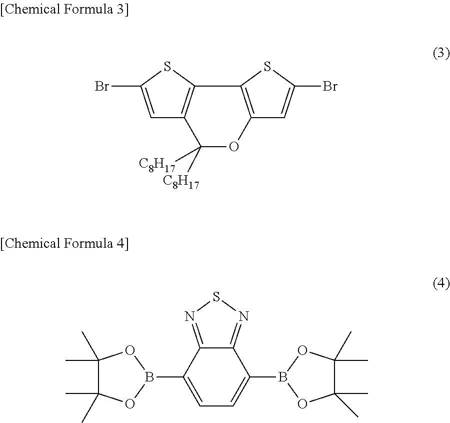

As the electron-donor compound, a macromolecular compound having a polystyrene-converted weight average molecular weight of 3000 to 10000000 that is calculated using a polystyrene standard sample is preferably used. When the weight average molecular weight is lower than 3000, defects in film formation may be generated at the time of device production. When the weight average molecular weight exceeds 10000000, solubility into a solvent and applicability at the time of cell production may be decreased. The weight average molecular weight of the electron-donor compound is more preferably 8000 to 5000000, and particularly preferably 10000 to 1000000.

The electron-donor compound may be used singly or in combination of two or more compounds.

Examples of the electron-acceptor compounds may include oxadiazole derivatives, anthraquinodimethane and derivatives thereof, benzoquinone and derivatives thereof, naphthoquinone and derivatives thereof, anthraquinone and derivatives thereof, tetracyano-anthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as C₆₀ and derivatives thereof, phenanthrene derivatives such as bathocuproine, metal oxides such as titanium oxide, and carbon nanotubes. As the electron-acceptor compounds, titanium oxide, carbon nanotubes, fullerenes, and fullerene derivatives are preferable, and fullerenes and fullerene derivatives are particularly preferable.

Examples of the fullerenes may include C₆₀ fullerene, C₇₀ fullerene, C₇₆ fullerene, C₇₈ fullerene, and C₈₄ fullerene.

Examples of the fullerene derivatives may include C₆₀ fullerene derivatives, C₇₀ fullerene derivatives, C₇₆ fullerene derivatives, C₇₈ fullerene derivatives, and C₈₄ fullerene derivatives. Examples of specific structures of the fullerene derivatives may include the following structures.

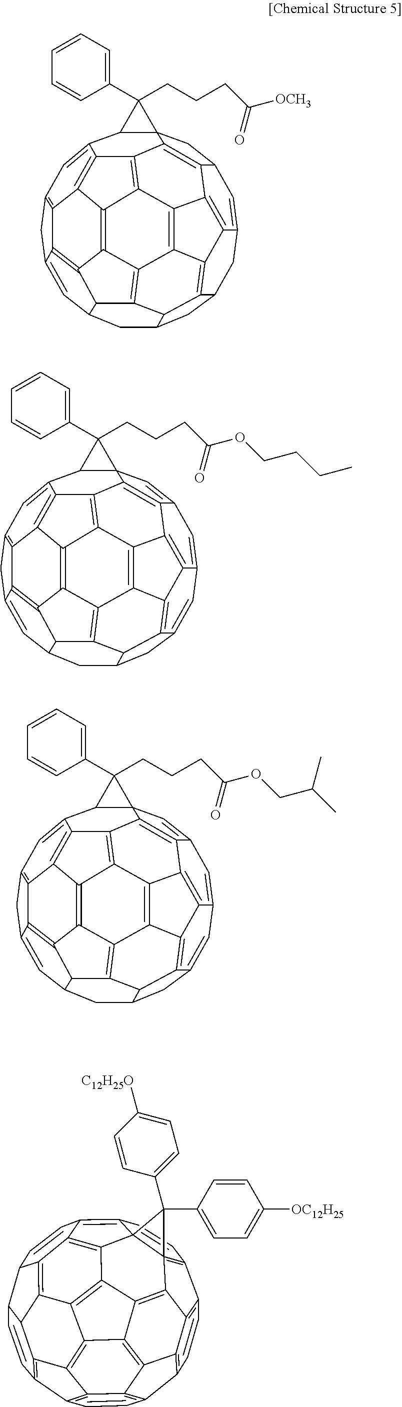

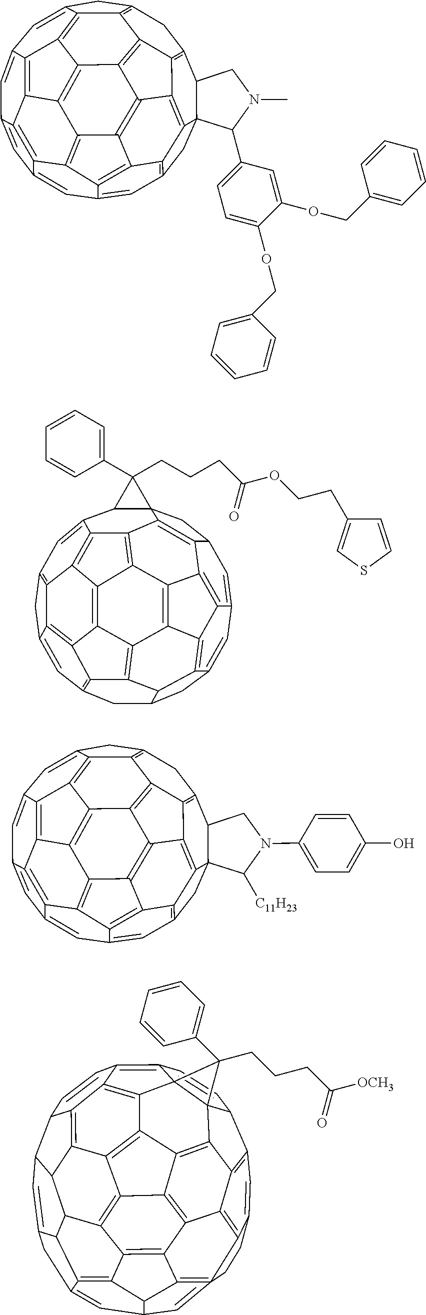

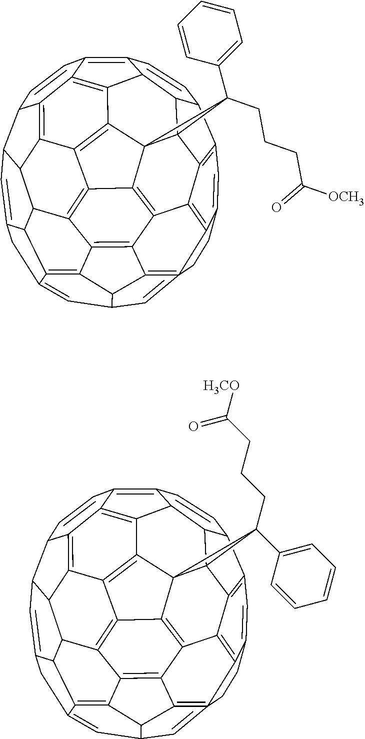

In addition, examples of the fullerene derivatives may include [5,6]-Phenyl C₆₁ butyric acid methyl ester ([5,6]-PCBM), [6,6]-Phenyl C₆₁ butyric acid methyl ester ([6,6]-PCBM, C₆₀ PCBM), [6,6]-Phenyl C₇₁ butyric acid methyl ester (C₇₀PCBM), [6,6]-Phenyl C₈₅ butyric acid methyl ester (C₈₄PCBM), and [6,6]-Thienyl C₆₁ butyric acid methyl ester.

As the electron-acceptor compounds, fullerenes, and fullerene derivatives are preferable and [5,6]-PCBM and [6,6]-PCBM are more preferable among the specific examples described above. When the fullerene derivatives are used as the electron-acceptor compounds, a ratio of the fullerene derivative is preferably 10 to 1000 parts by weight, and more preferably 20 to 500 parts by weight, based on 100 parts by weight of the electron-donor compound.

The electron-acceptor compound is not limited to one compound, and combination of two or more of the compounds may be used.

Examples of the materials for the interlayer may include halides and oxides of alkali metals and alkaline-earth metals such as lithium fluoride (LiF). Also, examples of the materials for the interlayer may include fine particles of inorganic semiconductor such as titanium oxide, and PEDOT (poly-(3,4)-ethylenedioxythiophene). Among them, the interlayer in the anode side is preferably PEDOT, and the interlayer in the cathode side is preferably alkali metals (more preferably LiF).

The organic photovoltaic cell may have a substrate. The substrate may be located outside of one of the electrodes as illustrated in FIG. 1 to FIG. 4, or may be in the form of sandwiching the cell between two substrates as illustrated in FIG. 5. The substrate may be any substrate that is not chemically changed when the electrode is formed and when a layer comprising an organic material is formed. Examples of the material for the substrate may include glasses, plastics, polymer films, and silicon. When the substrate is opaque, the electrode opposite to the substrate (in other words, the electrode in the pair of electrodes that is further from the substrate) is preferably transparent or translucent.

A method for manufacturing an organic photovoltaic cell of the present invention may include a method including covering at least a part of an operative part (a pair of electrodes, an active layer and an interlayer that is optionally provided) with a sealing layer comprising a substance having an oxygen absorption property and/or a water absorption property.

Examples of methods for covering with the sealing layer may include a method in which a solution comprising materials for the sealing layer is prepared, and the solution is applied to a place (for example, the surface of the electrode) where the sealing layer in the operative part previously formed will be located, a method in which the operative part is immersed into the solution, and a spraying method. In addition, the substrate may be bonded onto the sealing layer. The sealing layer and the substrate can be bonded easier by forming the sealing layer itself from a material having adhesion properties. Specifically, the sealing layer may be formed by, for example, arranging the solution comprising the materials for the sealing layer at an area in an organic solar cell element being intended to be covered, locating a transparent or translucent substrate (for example, glass) thereon, and then performing irradiation using a mercury lamp to cure the arranged solution.

Examples for manufacturing the operative part in the organic photovoltaic cell of the present invention may include an example in which after forming an electrode on the substrate, an active layer is formed, and thereafter, an electrode is formed on the active layer, and then a sealing layer is formed. From this example, the organic photovoltaic cells shown as examples in FIG. 1, FIG. 2, FIG. 4, and FIG. 5 are obtained. The organic photovoltaic cell shown as an example in FIG. 3 may be formed by, after forming an electrode on a substrate and forming an interlayer on the electrode, forming an active layer as described above, and thereafter, forming an interlayer on the active layer, and further forming an electrode and a sealing layer on the interlayer.

Examples of methods for forming the active layer may include a method in which a solution comprising the organic compound is prepared and a film made from this solution is formed. The solution comprising the organic compound can be prepared by dissolving the organic compound into a solvent. The solvent may be either water or an organic solvent, and is adequately selected depending on types of the organic compound, that is, the electron-donor compound and the electron-acceptor compound, and the like. Examples of the organic solvents may include unsaturated hydrocarbon-based solvents such as toluene, xylene, mesitylene, tetralin, decalin, bicyclohexyl, n-butylbenzene, sec-butylbenzene, and tert-butylbenzene; halogenated saturated hydrocarbon-based solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon-based solvents such as chlorobenzene, dichlorobenzene, and trichlorobenzene; and ether-based solvents such as tetrahydrofuran and tetrahydropyran. Among them, the halogenated unsaturated hydrocarbon-based solvents are preferable, and dichlorobenzene is more preferable, and ortho-dichlorobenzene is further more preferable.

An added amount of the organic compound to the solvent is not particularly limited and optimum range of the amount can be adequately selected. The amount is usually 0.1% by weight or more, preferably 0.3% by weight or more, and more preferably 0.5% by weight or more.

When the solution comprising the organic compound is prepared as a solution comprising both of the electron-donor compound and the electron-acceptor compound, these organic compounds are added so that a total amount of the electron-donor compound and the electron-acceptor compound in the solution is usually 0.2% by weight or more, preferably 0.5% by weight or more, and more preferably 1% by weight or more. A formulation ratio of the electron-donor compound and the electron-acceptor compound can be adjusted so that the ratio is usually 1-20:20-1, preferably 1-10:10-1, and more preferably 1-5:5-1. When a solution comprising the electron-donor compound and a solution comprising the electron-acceptor compound are separately prepared, the electron-donor compound or the electron-acceptor compound in the solution is added so that the amount is usually 0.4% by weight or more, preferably 0.6% by weight or more, and more preferably 2% by weight or more.

The solution comprising the organic compound may be filtered, if required. Accordingly, the photovoltaic efficiency can further be improved. A pore diameter of the filter is usually 10 to 0.1 μm, preferably 5 to 0.1 μm, and more preferably 0.15 to 0.1 μm.

Film formation of the active layer may be performed by, for example, applying the solution comprising the organic compound onto the electrode or the interlayer and then volatilizing the solvent. Example of methods for applying may include a coating method.

Examples of the coating method may include a spin coating method, a casting method, a microgravure coating method, a gravure coating method, a bar coating method, a roll coating method, a wire-bar coating method, a dip coating method, a spray coating method, a screen printing method, a gravure printing method, a flexographic printing method, an offset printing method, an ink-jet printing method, a dispenser printing method, a nozzle coating method and a capillary coating method. Among them, the spin coating method, the flexographic printing method, the gravure printing method, the ink-jet printing method and the dispenser printing method are preferable, and the spin coating method is more preferable.

When the organic photovoltaic cell in which the active layer is a bulk hetero-junction type is manufactured, the active layer can be formed by, for example, applying a solution comprising both of the electron-donor compound and the electron-acceptor compound onto the electrode or the interlayer, and then volatilizing the solvent.

On the other hand, when the organic photovoltaic cell in which the active layer is a pn hetero-junction type is manufactured, the electron-donor layer is formed by preparing a solution comprising the electron-donor compound and a solution comprising the electron-acceptor compound, applying the solution comprising the electron-donor compound onto the electrode or the interlayer and then volatilizing the solvent to form an electron-donor layer. Subsequently, the solution comprising the electron-acceptor compound is applied onto the electron-donor layer and then the solvent is volatilized to form the electron-acceptor layer. As described above, the active layer having two-layer constitution can be formed. Formation order of the electron-donor layer and the electron-acceptor layer may be reverse order of the order described above.

The thickness of the active layer is usually 1 nm to 100 μm, preferably 2 nm to 1000 nm, more preferably 5 nm to 500 nm, and further more preferably 20 nm to 200 nm.

In formation of the electrode, various thin film formation methods can be adequately selected, in the consideration of conditions such as the type of electrode material and thickness. Also, in formation of the interlayer, various thin film formation methods can be adequately selected, in the consideration of conditions such as the type of interlayer material and thickness. When the formation of the electrode and/or the interlayer is or are performed by film formation using the solution, the coating method described above, and the like may be adequately employed. In addition, a vacuum evaporation method, a sputtering method, a chemical vapor deposition method (CVD), and the like may be employed. After the electrode is formed on the substrate, the active layer can be formed directly on the electrode. Or, the active layer may be formed after optionally subjecting the electrode to other processes such as heating, ultraviolet-ozone treatment, and exposure to the atmosphere.

Example of the materials for the interlayer may include halides and oxides of alkali metals and alkaline-earth metals such as lithium fluoride (LiF). Also, examples of the materials for the interlayer may include fine particles of inorganic semiconductor such as titanium oxide, and PEDOT (poly-(3,4)-ethylenedioxythiophene). Among them, the interlayer in the anode side is preferably PEDOT, and the interlayer in the cathode side is preferably alkali metals (more preferably LiF).

An outline of operation mechanism of the organic photovoltaic cell is described. Energy of light that is incident though the transparent or translucent electrode is absorbed by the electron-acceptor compound such as the fullerene derivatives (an n-type organic semiconductor) and/or the electron-donor compound such as the macromolecular compound (a p-type organic semiconductor), whereby exciters in which electrons and holes are combined are generated. When the generated exciters move and reach to a hetero-junction interface where the electron-acceptor compound and the electron-donor compound are adjacent, difference of each of HOMO energy and LUMO energy at the interface causes separation of electrons and holes and generates charges (electrons and holes) that can move independently. The organic photovoltaic cell can take out electric energy (electric current) to outside of the cell by moving the generated charges to each of the electrodes.

The organic photovoltaic cell manufactured by the method for manufacturing of the present invention generates photovoltaic power between the electrodes by irradiating the electrodes that are transparent or translucent electrodes with light such as sunlight. Therefore, the organic photovoltaic cell may operate as an organic thin film solar cell. The organic thin-film solar cells in plurality may be stacked to be used as an organic thin-film solar cell module.

The organic photovoltaic cell may be operated as an organic optical sensor because photocurrent is flown by applying light from the transparent or translucent electrode in a state in which voltage is applied between the electrodes or in a state in which voltage is not applied. The plurality of the organic optical sensors may be stacked to be used as an organic image sensor.

The organic thin film solar cell can basically form the same module structure as that of a conventional solar cell module. In the solar cell module, a structure is formed in which a cell is generally constituted on a supporting substrate made of metals, ceramics, or the like, and a filling resin, protecting glass, or the like covers the cell, whereby light is taken from the opposite side of the supporting substrate. However, it is also possible that a structure be formed in which a supporting substrate being transparent and made of transparent materials such as reinforced glass is used as the supporting substrate and the cell is constituted on the supporting substrate, whereby light is taken from the transparent supporting substrate side. Specifically, module structures referred to as a superstraight type, a substrate type, and a potting type; a substrate-integrated module structure used for an amorphous silicon solar cell and the like; and other structures are known. The module structure of the organic thin film solar cell of the present invention may be adequately selected from these module structures depending on intended use, and place and environment of use.

A representative module structure referred to as the superstraight type or the substrate type forms a structure in which the cells are arranged at constant intervals between the supporting substrates whose one side or both sides is or are transparent and to which antireflection treatment is applied; the adjacent cells are connected with each other by a metal lead, a flexible wiring or the like; a collecting electrode is arranged at an outer edge part; and generated electric power is taken out to outside. In order to protect the cell and to improve power collection efficiency, various kinds of plastic materials such as ethylene-vinyl acetate (EVA) may be used, depending on purposes, in the form of a film or a filling resin between the substrate and the cell. When the module is used in places where the surface is not required to be covered with a hard material such as a place where impact from outside does not often occur, one side of the supporting substrates may be eliminated by constituting a surface protecting layer with a transparent plastic film or by curing the filling resin to provide a protecting function. In order to secure sealing of the inside and rigidity of the module, circumference of the supporting substrate is usually fixed by sandwiching the circumference between frames made of metal. From the same reason, a gap between the supporting substrate and the frames is usually tightly sealed with a sealing material. When a flexible material is used as a material for the cell itself, a material for the supporting substrate, and a material for the filling material and the sealing material, the solar cell can be constituted on a curved surface.

In the case of a solar cell using a flexible support such as a polymer film, a main body of the solar sell can be manufactured by sequentially forming the cell with pulling out the support in the form of a roll, cutting the support in a desired size, and then sealing the circumference part by a material having flexibility and a moisture-proof property. In the solar cell using the flexible support, a module structure referred to as “SCAF” described in Solar Energy Materials and Solar Cells, 48, p 383-391 can be used. The solar cell using the flexible support can be used by fixing the module on curved glass and the like with an adhesive.

If an insoluble component and/or dust exists or exist in the solution at the time of film formation, cracks may be generated on the coating film. In addition, agglomerated particles may be generated by forming nucleus from the insoluble component and/or the dust. Generation of the cracks and agglomerated flow causes phenomena such as electric or chemical contact failure at a junction interface, generation of leak current, and the like. According to the present invention, generation of these decreases can be decreased, whereby photovoltaic efficiency can be improved.

### EXAMPLES

### Example 1

### Manufacture of Organic Photovoltaic Cell

A glass substrate on which ITO having a film thickness of about 150 nm formed by a spattering method has been patterned was washed with an organic solvent, an alkaline detergent, and ultrapure water, and was dried. Ultraviolet-ozone treatment was performed to the substrate using an ultraviolet-ozone device by setting the ITO surface upside.

A suspension of an aqueous solution in which poly-(3,4)-ethylenedioxythiophene/polystyrene sulphonic acid were dissolved in water (Baytron P TP AI 4083, manufactured by H.C. Starck-V TECH Ltd.) was filtered with a filter having a pore diameter of 0.5 μm. A film having a thickness of 70 nm was formed on an ITO side of the substrate by applying the suspension after filtration by a spin coating method. The applied suspension was dried on a hot plate at 200° C. for 10 minutes in the atmosphere.

Subsequently, an ortho-dichlorobenzene solution in which the macromolecular compound A and [6,6]-Phenyl C61 butyric acid methyl ester ([6,6]-PCBM) were added in a weight ratio of 1:3 was prepared. An added amount of the macromolecular compound A was 1% by weight to ortho-dichlorobenzene. The macromolecular compound A had a polystyrene-converted weight average molecular weight of 17000 and a polystyrene-converted number average molecular weight of 5000. A light absorption edge wavelength of the macromolecular compound A was 925 nm.

Thereafter, the solution described above was filtered with a filter having a pore diameter of 0.5 μm. After the obtained extract was spin-coated, drying was performed in N₂ atmosphere.

On the upper surface of the active layer formed as described above, the electrode was formed by film forming LiF having a film thickness of about 2.3 nm and subsequently Al having a film thickness of about 70 nm in a resistance heating deposition device.

Using a sealing material made by mixing and kneading CaO fine particles having an average particle diameter of 1 μm or less (1 μm to 800 nm) and an epoxy resin being an ultraviolet curing resin (trade name: UV RESIN XNR 5516Z, manufactured by Nagase ChemteX Corporation) so that an amount of CaO fine particles to the resin was 10% by weight, the sealing material was applied on the electrode in a thickness of 100 μm, and a substrate was further bonded together for sealing.

### Example 2

An organic photovoltaic cell was manufactured in a similar way in Example 1 except that P3HT was used as an electron-donor compound (a p-type semiconductor material) instead of the macromolecular compound A and a ratio to C60PCBM was 1:0.8.

### Comparative Example 1

An organic thin film solar cell was manufactured in the same way as Example 1 except that CaO fine particles were not comprised in the sealing material.

### Comparative Example 2

An organic thin film solar cell was manufactured in the same way as Example 2 except that CaO fine particles were not comprised in the sealing material.

(Evaluation of Photovoltaic Efficiency)

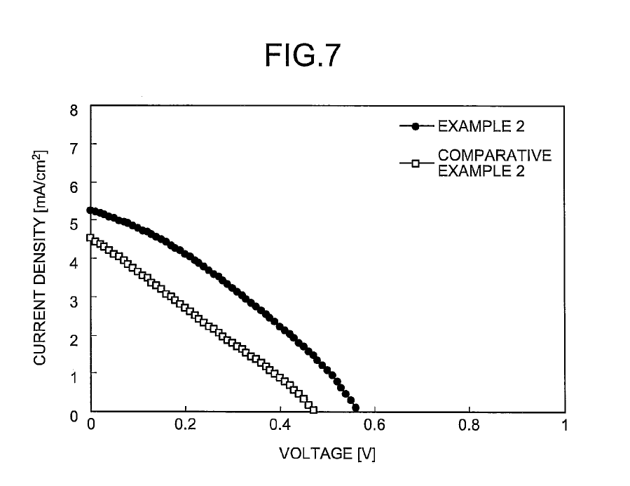

A shape of the organic thin film solar cells being the organic photovoltaic cell obtained in Examples and Comparative Examples was a square of 2 mm×2 mm. After leaving the organic thin film solar cells for 7 days in a dark place, solar cell properties were measured Measurement was performed as follows. Short-circuit current density, open-circuit voltage, a fill factor, and photovoltaic efficiency were measured by sweeping applied DC voltage to the cell at a constant rate of 20 mV/second using a spectrosensitometer CEP-2000 manufactured by BUNKOUKEIKI Co., Ltd. The short-circuit current density, the open-circuit voltage, the fill factor, the photovoltaic efficiency, serial resistance, and parallel resistance of the organic thin film solar cells in Examples and Comparative Examples are listed in Table 1. Current-voltage properties of Example 1 and Comparative Example 1 and current-voltage properties of Example 2 and Comparative Example 2 are illustrated in FIG. 6 and FIG. 7, respectively.

Both of the organic thin film solar cells in Example 1 to Example 2 have high photovoltaic efficiency for long period and have long lifetime, compared with the organic thin film solar cells in Comparative Example 1 to Comparative Example 2.

TABLE 1

| | | | COMPARATIVE | COMPARATIVE |
|---|---|---|---|---|
| | EXAMPLE 1 | EXAMPLE 2 | EXAMPLE 1 | EXAMPLE 2 |
| SHORT-CIRCUIT | 10.54 | 5.24 | 9.79 | 4.51 |
| CURRENT DENSITY | | | | |
| [mA/cm²] | | | | |
| OPEN-CIRCUIT | 0.50 | 0.56 | 0.51 | 0.47 |
| CURRENT DENSITY [V] | | | | |
| FILL FACTOR | 0.46 | 0.33 | 0.41 | 0.26 |
| SERIAL RESISTANCE | 4.25 | 7.45 | 14.09 | 7.10 |
| (Ωcm²) | | | | |
| PARALLEL RESISTANCE | 705.04 | 916.61 | 551.97 | 1180.30 |
| (Ωcm²) | | | | |
| PHOTOVOLTAIC | 2.42 | 0.97 | 2.04 | 0.56 |
| EFFICIENCY [%] | | | | |

### INDUSTRIAL APPLICABILITY

The present invention is useful because the present invention provides the organic photovoltaic cell.

1. An organic photovoltaic cell comprising:
an operative part that comprises a pair of electrodes and an active layer that is located between the pair of electrodes and comprises an organic compound; and
a sealing layer covering at least a part of the operative part, wherein
the sealing layer comprises a substance having an oxygen absorption property and/or a water absorption property.

2. The organic photovoltaic cell according to claim 1, wherein the substance having the oxygen absorption property and/or the water absorption property is a metal oxide.

3. The organic photovoltaic cell according to claim 2, wherein the metal oxide is calcium oxide.

4. The organic photovoltaic cell according to claim 1, wherein the substance having the oxygen absorption property and/or the water absorption property is a particle having a particle diameter of 1 μm or less.

5. The organic photovoltaic cell according to claim 1, wherein a substrate is mounted on the sealing layer.

6. A method for manufacturing an organic photovoltaic cell, the method comprising:
covering at least a part of an operative part with a sealing layer, the operative part comprising a pair of electrodes and an active layer that is located between the pair of electrodes and comprises an organic compound, the sealing layer comprising a substance having an oxygen absorption property and/or a water absorption property.
